(19) United States
(12) Patent Application Publication
(10) Pub. No.: US 2004/0229135 A1
(43) Pub. Date: Nov. 18, 2004

(54) Multiple exposure method for circuit performance improvement

(76) Inventors: Jun Wang, Hong Kong (HK); Alfred K. Wong, Brookline, CA (US)

Correspondence Address: DICKSTEIN SHAPIRO MORIN & OSHINSKY LLP, 1177 AVENUE OF THE AMERICAS (6TH AVENUE), 41 ST FL., NEW YORK, NY, 10036-2714, US

(21) Appl. No.: 10/787,169

(22) Filed: Feb. 27, 2004

Related U.S. Application Data
(60) Provisional application No. 60/450,496, filed on Feb. 27, 2003.

(51) Int. Cl. G03C 5/00; G03F 9/00; H01L 23/48

(52) U.S. Cl. 430/5; 430/394; 430/311

(57) ABSTRACT

An optical lithography method is disclosed that uses multiple exposures to decrease the minimum grid pitch of regularly spaced features. The desired grid pitch is selected to minimize the circuit area growth arising from the use of a grid constraint during layout. The desired grid is decomposed into at least two interleaved mask grids having a mask grid pitch that is greater than the desired grid pitch. Each mask grid is exposed to print a portion of the desired grid until the complete desired grid is printed to the die.

### CROSS REFERENCE TO RELATED APPLICATION

The present application claims priority to U.S. Provisional Application No. 60/450,496, filed Feb. 27, 2003, the entirety of which is incorporated herein by reference.

### FIELD OF THE INVENTION

The present invention relates to optical lithography. More specifically, the invention relates to advanced optical lithography methods for decreasing the minimum grid pitch of a regularly placed layout. The method of the invention can be used to decrease circuit area and improve circuit performance.

### BACKGROUND OF THE INVENTION

Optical lithography remains the dominant technology for integrated circuit fabrication even as the size of the semiconductor features shrink to the 100-200 nm range. The minimum size that can be defined is called the critical dimension, CD, and is given by the following equation:

$$C D = {k}_{1} \frac{λ}{N A} \qquad ( 1 )$$

where λ is the wavelength of the exposure light, NA is the numerical aperture of the projection system, and k₁ is the process-related factor. The CD may be reduced by decreasing k₁ and for particular exposure systems having a fixed A and NA, decreasing k₁ is the only method of decreasing CD. The image quality, however, degrades noticeably when k₁ is reduced below 0.75.

Resolution enhancement techniques (RETs) are employed to improve the image quality when k₁ is less than 0.75. Examples of RETs include modified illumination, phase-shift masking (PSM), and optical proximity correction (OPC).

A. K Wong, “Resolution Enhancement Techniques in Optical Lithography,” SPIE Press, Washington, 2001 discloses several kinds of illumination modes that are suitable for different mask patterns. Optimizing the illumination source, however, is very difficult because image quality not only depends on the size and shapes of the pattern but also depends on the local environment of each mask feature. For example, randomly placed contacts produce regions of densely spaced contacts and regions of sparsely spaced contacts on the same mask. An illumination source optimized for the dense region will result in high image quality in the dense region but may also result in poor image quality in the sparse region.

By considering circuit manufacturability in the layout design, it is expected that the k₁, factor can be further reduced by fabrication-friendly layout in which the circuit pattern configurations are limited to facilitate lithography optimization.

Excessive lithography friendliness may be so restrictive on layout compaction that circuit area increases unacceptably. Therefore, there remains a need for methods that allow for lithography optimization to reduce the CD of the circuit while not increasing the growth of the circuit area.

### SUMMARY

One embodiment of the present invention is directed to a method of optical lithography wherein features placed on a grid characterized by a grid pitch, the grid pitch being selected to minimize the circuit area increase caused by the use of the grid, are printed to the die through at least two masks by multiple exposures wherein each mask comprises a mask grid characterized by a mask grid pitch that is larger than the grid pitch.

The method is suited for the imaging of regularly-placed fabrication-friendly contacts onto a wafer. The regular placement of contacts enables more effective use of resolution enhancement technologies, which in turn allows in a reduction of the minimum contact pitch and size.

One approach of fabrication-friendly contacts is to snap contacts on grid points and introduce assist contacts at the grid points that do not have a contact. The assist contacts are sized such that they do not print onto the die but nevertheless create a mask spectrum that allows the illumination to be optimized.

For the application of regularly-placed contacts on standard cells in application-specific integrated circuits (ASICs), contacts and assist contacts are placed on a grid with pitch smaller than the minimum pitch of single-exposure lithography to get-a smaller circuit area. Although the pitch between contacts and assist contacts is smaller than the minimum pitch of single-exposure lithography, the pitches between any two real contacts satisfies the design rules of single-exposure lithography.

The dense grid of contacts and assist contacts are separated into two sparser grids on two masks with the grid pitch occurring at the diagonal direction:

pₘᵢₙ=\sqrt{pₓ²+p_{y}²}, (2)

where pₘᵢₙ is the grid pitch of the sparser grid, pₓ and p_{y} are two grid pitches of the dense grid in two perpendicular directions. Although pₓ and p_{y} are smaller than the minimum pitch of single-exposure lithography, pₘᵢₙ can be larger. Thus, the two sparser grids are within the resolution limit of one exposure. Sequential exposures of these two masks print all contacts onto the die.

With the minimum grid pitch occurring at the diagonal direction in the two exposures, the poles of quadrupole illumination for the contact lithography should be placed on the x- and y-axes with distances to zero point determined by pₓ and p_{y}.

### BRIEF DESCRIPTION OF THE DRAWINGS

The invention will be described by reference to the preferred and alternative embodiments thereof in conjunction with the drawings in which:

FIG. 1a-d is an illustration of one embodiment of the present invention;

FIG. 2a is a diagram of the illumination source used for an X-Y grid layout;

FIG. 2b is a diagram of the illumination source used in the embodiment of FIG. 1;

FIG. 3 is a diagram illustrating the feature of a standard cell;

FIG. 4a is a diagram showing a representative contact pitch distribution in the height direction for standard cells;

FIG. 4b is a diagram showing a representative contact pitch distribution in the width direction for standard cells.

### DETAILED DESCRIPTION OF THE PREFERRED AND ALTERNATIVE EMBODIMENTS

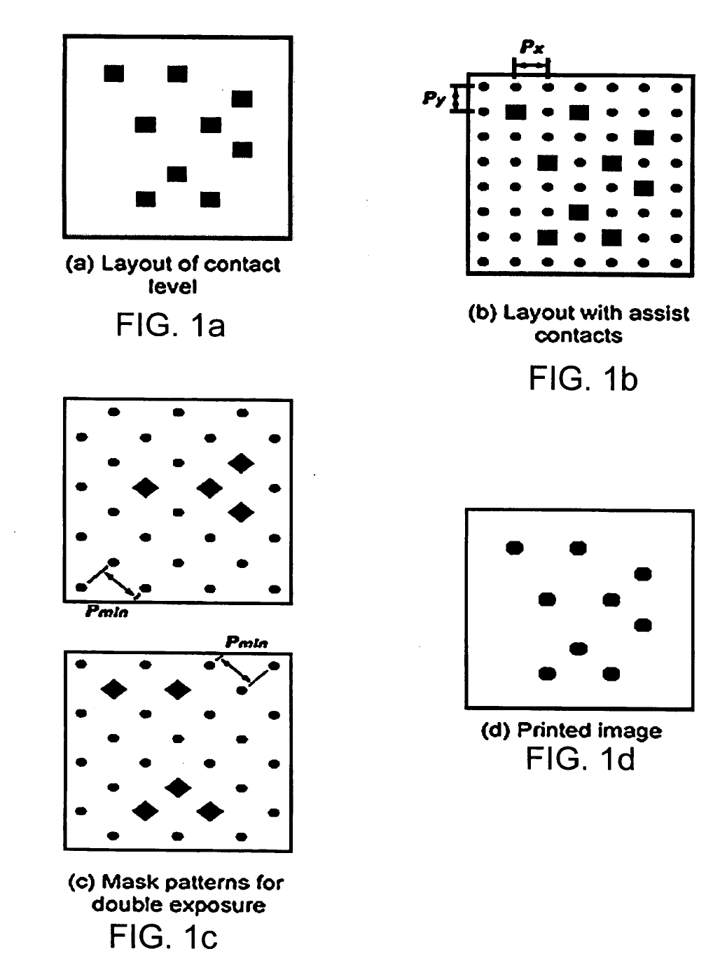

FIG. 1 illustrates one embodiment of the present invention. In fabrication-friendly layout, contacts are placed on a grid (FIG. 1a). Assist contacts are added into the grid points that do not have a contact (FIG. 1b). The assist contacts are sized such that they do not print onto the die but create a mask spectrum that allows the illumination to be optimized.

To get a smaller circuit area after snapping all contacts on a grid, the grid pitches in FIG. 1b, pₓ and p_{y}, are smaller than the minimum pitch of single-exposure lithography.

Although the pitch between contacts and assist contacts is smaller than the minimum pitch of single-exposure lithography, the pitches between any two real contacts always satisfy the design rule of the single-exposure lithography.

The dense grid of contacts and assist contacts (FIG. 1b) are separated into two sparser grids on two masks (FIG. 1c) with the grid pitch occurring at the diagonal direction:

pₘᵢₙ=\sqrt{pₓ²+p_{y}²}, (3)

where pₘᵢₙ is the grid pitch of the sparser grid, pₓ and p_{y} are two grid pitches of the dense grid in two perpendicular directions. Since the original dense grid is decomposed into several sparser ones, it is called a virtual grid. When pₓ is equal to p_{y}, pₘᵢₙ is roughly 144% of pₓ and p_{y}. Although pₓ and p_{y} are smaller than the minimum pitch of single-exposure lithography, pₘᵢₙ can be larger than it. That makes the two sparser grids within the resolution limit of one exposure.

Sequential exposures of these two masks print all contacts on the virtual grid on the die (FIG. 1d). The regular placement of features in two masks enables lithography optimization and leads to a reduced minimum contact size and pitch. While an overlay error on either contact mask would reduce yield, and two masks will cost more than one, since mask write times depend on the number of features written, which remains constant, and faster tools can be used for larger pitches, reticle costs should not double. It should be noted that this double exposure method works because there are no nearest-neighboring contacts on the virtual grid. The particular example in FIG. 1 places assist contacts or actual contacts at all virtual grid points. Without that RET-based restriction, a single contact mask might suffice for the contacts of FIG. 1a.

The inventors have discovered that the reduced virtual grid pitch, coupled with about a 10% reduction in CD, the result of the lithography optimization enabled by regular placement of contacts, negates the expansion of the circuit area resulting from the additional constraint placed on the layout step of requiring the contacts to be snapped to a grid and leads to smaller average standard cell area. Power consumption and intrinsic delay of standard cells also improve with the decrease of cell area.

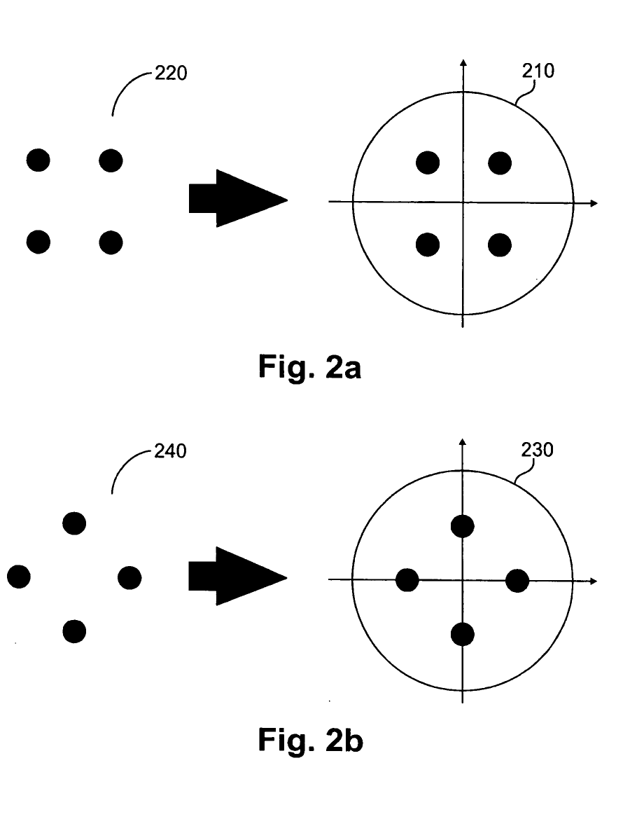

FIG. 2a is a diagram of the illumination source used for an X-Y grid layout. In one type of modified illumination RET, a quadrupole illumination source 210 is aligned to the grid axes of the grid 220. In one embodiment of the present invention, although the virtual grid has grid axes aligned with the X and Y directions, the first and second grid patterns 240 are aligned with the diagonal directions. In a preferred embodiment, the quadrupole illumination source 230 for the first and second grid patterns 240 are also aligned with the diagonal directions. The poles of quadrupole illumination 230 for the first and second grid patterns 240 are placed on the x- and y-axes with distances to zero point determined by pₓ and p_{y}.

A 250 nm standard cell library is used as an illustrative example of one embodiment of the present invention. Standard cells are important features for application-specific integrated circuit (ASIC) design. A standard cell based ASIC design typically comprises three types of cells: I/O cells, mega cells, and standard cells. I/O cell are laid on the periphery of the die as connection points to outside circuitry. Mega cells are typically pre-designed mega-logic features such as RAM and ROM. Standard cells are micro-logic features that primarily provide basic logic functions such as Boolean operations and flip-flops.

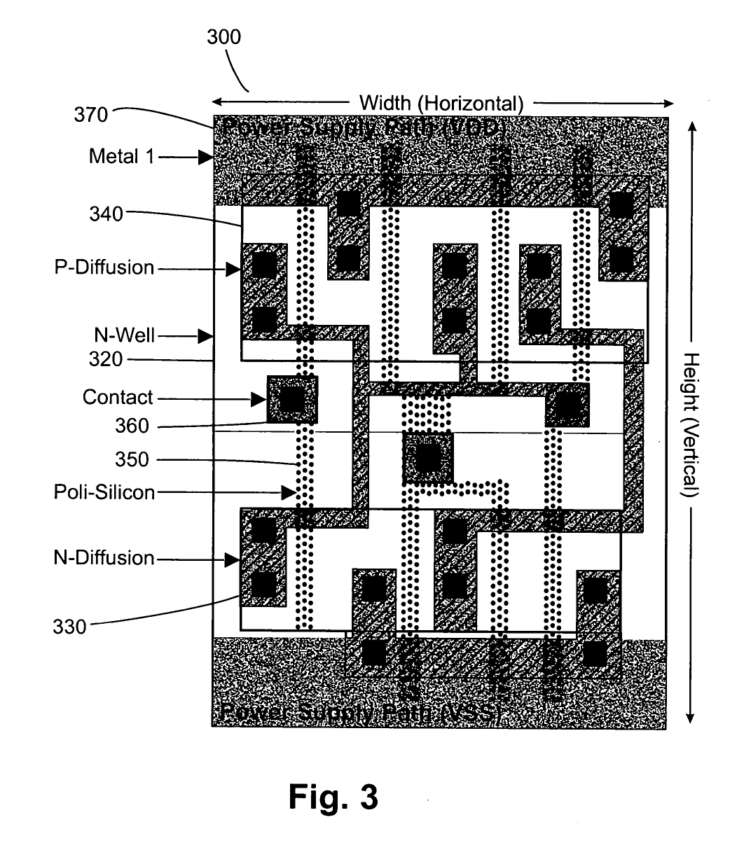

FIG. 3 is a diagram illustrating the feature of a standard cell 300. Each standard cell in a library is rectangular with a fixed height but varying widths. The cells are placed in rows with overlapping power supply paths. A standard cell typically has an N-well layer 320, an N-diffusion layer 330, a P-diffusion layer 340, a poly-silicon layer 350, a contact layer 360, and a metal-1 layer 370. The N-well 320, N-diffusion 330, P-diffusion 340 and poly-silicon 350 form P-MOS and N-MOS inside the cells. The poly-silicon 350 also serves as an intra-cell routing path. The contacts 360 form connections between the routing layers and the under layers.

The height of a cell is typically given as the number of metal-1 tracks over the cells in the height direction. A metal-1 track comprises the metal-1 path and the space between metal-1 paths. The typical height of a standard cell is 10 tracks, where three tracks are used for power supply paths and the remaining seven tracks are for intra-cell design. Because the height is fixed in a library, any change in area caused by snapping contacts to a grid is reflected as a change in the cell width.

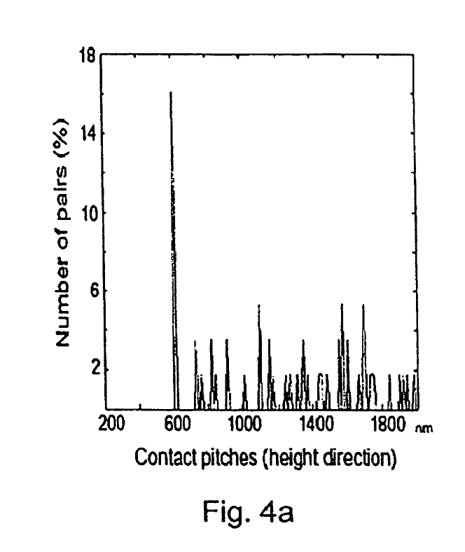

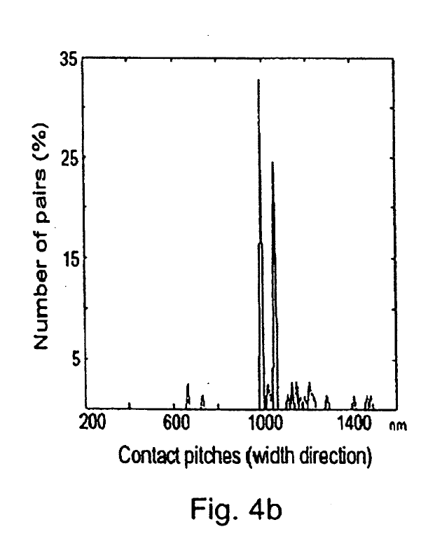

FIG. 4a is a diagram showing a representative contact pitch distribution of standard cells in the height direction. The most frequent pitch pair is about 600 nm, which most likely reflects the minimum pitch of the metal-1 path. Therefore the minimum pitch of the metal-1 path may be selected as the grid pitch or multiple of the grid pitch in the height direction. To get a smaller final cell area, a half of metal-1 pitch should be selected as the horizontal grid pitch, p_{y}, of regularly-placed contacts in standard cells to relax the layout restriction in the vertical direction.

FIG. 4b is a diagram showing a representative contact pitch distribution of standard cells in the width direction. The minimum pitch pair is about 600 nm but the most frequent pitch pair is around 1000 nm. If the minimum pitch pair is selected as the grid pitch, the area of the cell will increase by about 20% because the most frequent pitch pairs at 1000 nm will rounded up to two grid pitches (1200 nm). Furthermore, FIG. 4b shows two peaks near 1000 nm. The two peaks reflect the distance between the source and drain in two types of MOSFETs in the standard cell. The narrow gate MOSFET has a larger source to drain distance than the wide gate MOSFET, thereby creating a double-peaked contact pitch distribution. The double peak may be eliminated by increasing the width of some narrow gate MOSFETs.

FIG. 4b indicates that the most frequent pitch pair is the source—drain pitch. If the source—drain pitch is selected as the grid pitch in the horizontal direction, however, the contacts for the gate, which are typically placed in the middle of source and drain contacts, will have to be aligned with either the source or drain contacts resulting in a large cell area increase. Therefore, a half source—drain pitch should be selected as the horizontal grid pitch, pₓ of regularly-placed contacts in standard cells.

The desired grid pitches, pₓ and p_{y}, however, are smaller than the minimum pitch of the contact layer. The desired grid is decomposed into two interleaved grids. Each interleaved grid has its grid axes aligned along the diagonals of the desired grid with an interleaved grid pitch equal to the diagonal pitch of the desired grid. It should be noted that the grid pitches, pₓ and p_{y}, can be different from each other.

In one embodiment, each grid location is populated by a real contact or an assist contact. The die is printed by projecting the first interleaved grid onto the die followed by projecting the second interleaved grid onto the die. The regular placement of features in two masks enables lithography optimization and leads to a reduced minimum contact size and pitch. The double exposure method creates the virtual grid on the die have the desired grid pitches from interleaved grids having pitches approximately 40% larger than the desired grid pitches.

In one embodiment, all of the features (real or assist) are initially arranged on one mask. However, that first mask cannot be printed because the grid pitches of the features in that mask are smaller than the minimum pitch of single-exposure lithography. The features (real or assist) in that first mask are then separated into two masks. The grid pitches of the features in the two mask are larger than the minimum pitch of single-exposure lithography. The double exposures of those two masks print all real features onto the wafer. It should be noted that the features (real or assist) can be separated into more than two masks.

Having described at least illustrative embodiments of the invention, various modifications and improvements will readily occur to those skilled in the art and are intended to be within the scope of the invention. Accordingly, the foregoing description is by way of example only and is not intended as limiting.

What is claimed is:

1. A method of imaging features onto a wafer comprising:
establishing a grid having grid pitches;
arranging a plurality of real features on the grid;
creating one mask, the mask including all of the plurality of real features and a plurality of assist features, the assist features being sized such that they do not print while allowing an illumination to be optimized; and
imaging the real features onto a wafer.

2. The method of imaging features according to claim 1, wherein the assist features are introduced at grid points that do not have any of the plurality of real features.

3. The method of imaging features according to claim 1 wherein the grid has a grid pitch pₓ in a direction and a grid pitch p_{y} in a perpendicular direction.

4. The method of imaging features according to claim 1 wherein grid pitches, pₓ and p_{y}, are selected to minimize circuit area.

5. The method of imaging features onto a wafer according to claim 3, wherein the grid pitches in two perpendicular directions, pₓ and p_{y}, are smaller than a minimum pitch of single-exposure lithography.

6. The method of imaging features according to claim 5, wherein a distance between two adjacent real features is no less than the minimum pitch of single-exposure lithography.

7. A method of imaging features onto a wafer comprising:
establishing a grid having grid pitches;
arranging a plurality of real features on the grid;
arranging a plurality of assist features on the grid points;
creating two masks, the first mask including a first subset of the plurality of real features and a first subset of the plurality of assist features, the second mask containing a second subset of the plurality of real features and a second subset of the plurality of assist features, the assist features being sized such that they do not print but nevertheless create a mask spectrum that allows an illumination to be optimized; and
imaging the real features onto the wafer.

8. The method of imaging features according to claim 7 wherein the grid has a grid pitch Pₓ in a direction and a grid pitch p_{y} in a perpendicular direction.

9. The method of imaging features according to claim 7, wherein grid pitches, Pₓ and p_{y}, are selected to minimize circuit area.

10. The method of imaging features according to claim 7, wherein the assist features are arranged on the grid points that do not have a real feature.

11. The method of imaging features onto a wafer according to claim 7, wherein the grid pitches in two perpendicular directions, pₓ and p_{y}, are smaller than a minimum pitch of single-exposure lithography.

12. The method of imaging features onto a wafer according to claim 11, wherein a distance between two adjacent real features is no less than the minimum pitch of single-exposure lithography.

13. A method of imaging features onto a wafer according to claim 7, wherein the first and second masks are sequentially exposed to print the features.

14. The lithography method according to claim 7, wherein the distance between two adjacent real features is no less than the minimum pitch of single-exposure lithography while the grid pitches in two perpendicular directions, pₓ and p_{y}, are smaller than the minimum pitch of single-exposure lithography.

15. The lithography method according to claim 14, wherein a diagonal distance between two adjacent features (real or assist features) is \sqrt{pₓ²+p_{y}²} where pₓ is the pitch between two adjacent features (real or assist features) in an x direction and p_{y} is the pitch between t two adjacent features (real or assist features) in a perpendicular direction of an x direction.

16. A mask set for imaging a die comprising:
a first mask, the first masking having a first set of real features and a first set of assist features; and
a second mask having a second set of real features and a second set of assist features,
wherein two adjacent features (real or assist features) in the first or second mask are spaced at no less than a minimum pitch for single-exposure lithography.

17. The mask set according to claim 16, wherein the first set of real features and the second set of real features create a set of real features for a single die.

18. A mask set for imaging a die according to claim 16, wherein the first set of real features is distinct from the second set of real features.

19. A mask set for imaging a die according to claim 16, wherein the first set of assist contacts is distinct from the second set of assist contacts.

20. The mask set for imaging a die according to claim 16, wherein a diagonal distance between two neighboring features (real or assist features) is \sqrt{pₓ²+p_{y}²} where pₓ is the pitch between two adjacent features (real or assist features) in an x direction and p_{y} is the pitch between two adjacent features (real or assist features) in the perpendicular direction of an x direction.

21. A method of imaging features onto a wafer comprising:
establishing a grid having a grid pitch;
arranging a plurality of real features on the grid;
creating at least one mask, the mask including at least one real feature and a plurality of assist features, the assist features being sized such that they do not print while allowing an illumination to be optimized; and
imaging the real feature onto a wafer.

22. The method of imaging features according to claim 21, wherein the assist features are introduced at grid points that do not have any of the plurality of real features.

23. The method of imaging features according to claim 21 wherein the grid has a grid pitch pₓ in a direction and a grid pitch p_{y} in a perpendicular direction.

24. The method of imaging features according to claim 21 wherein grid pitches, pₓ and p_{y} are selected to minimize circuit area.

25. The method of imaging features onto a wafer according to claim 23, wherein the grid pitches in two perpendicular directions, pₓ and p_{y}, are smaller than the minimum pitch of single-exposure lithography.

26. The method of imaging features according to claim 25, wherein a distance between two adjacent real features is no less than a minimum pitch of single-exposure lithography.

27. A method of imaging features onto a wafer comprising:
establishing a grid having a grid pitch;
arranging a plurality of features on the grid;
arranging a plurality of assist features on the grid points;
creating at least two masks, the first mask including a first subset of the plurality of features and a first subset of the plurality of assist features, the second mask containing a second subset of the plurality of features and a second subset of the plurality of assist features, the assist features being sized such that they do not print but nevertheless create a mask spectrum that allows an illumination to be optimized; and
imaging the features onto the wafer.

28. The method of imaging features according to claim 27, wherein the assist features are introduced at grid points that do not have any of the plurality of real features.

29. The method of imaging features according to claim 27 wherein the grid has a grid pitch pₓ in a direction and a grid pitch p_{y} in a perpendicular direction.

30. The method of imaging features according to claim 27 wherein grid pitches, pₓ and p_{y}, are selected to minimize circuit area.

31. The method of imaging features onto a wafer according to claim 29, wherein the grid pitches in two perpendicular directions, Pₓ and p_{y}, are smaller than the minimum pitch of single-exposure lithography.

32. The method of imaging features according to claim 31, wherein a distance between two adjacent real features is no less than a minimum pitch of single-exposure lithography.
